(19) United States
(12) Patent Application Publication
(10) Pub. No.: US 2026/0231582 A1
(43) Pub. Date: Aug. 6, 2026

(54) ELECTRONIC DEVICE AND MANUFACTURING METHOD OF THEREOF

(71) Applicant: Innolux Corporation, Miaoli County (TW)

(72) Inventors: Chun-Hsiang Chang, Miaoli County (TW); Yu-Wen Chen, Miaoli County (TW); Yu-Wei Tu, Miaoli County (TW); Yung-Hsun Wu, Miaoli County (TW)

(73) Assignee: Innolux Corporation, Miaoli County (TW)

(21) Appl. No.: 19/442,946

(22) Filed: Jan. 7, 2026

Related U.S. Application Data
(60) Provisional application No. 63/753,963, filed on Feb. 5, 2025.

(30) Foreign Application Priority Data
Aug. 21, 2025 (CN) 202511174945.X

(51) Int. Cl. H10H 29/49; H10H 29/01; H10H 29/02; H10H 29/03

(52) U.S. Cl. CPC H10H 29/49; H10H 29/012; H10H 29/02; H10H 29/03

(57) ABSTRACT

An electronic device and a manufacturing method of thereof are provided. The method includes providing a carrier and electronic components disposed thereon, the electronic components include first and second electronic components; providing a circuit substrate including serial pad combinations, one serial pad combination includes first to fourth pads, the second pad is electrically connected to the third pad; picking up the first and second electronic components simultaneously; transferring the first and second electronic components onto the circuit substrate simultaneously. The first electronic component is correspondingly disposed on the first and second pads, the second electronic component is correspondingly disposed on the third and fourth pads, the first and second electronic components are connected in series with each other. The electronic device and the method thereof reduce the number of transfers of electronic components to be connected in series or improve the utilization rate of the electronic components on the carrier.

### CROSS-REFERENCE TO RELATED APPLICATION

This application claims the priority benefit of U.S. provisional application serial no. 63/753,963, filed on February 5, 2025, and China application serial no. 202511174945.X, filed on August 21, 2025. The entirety of each of the above-mentioned patent applications is hereby incorporated by reference herein and made a part of this specification.

### BACKGROUND

### Technical Field

The disclosure relates to an electronic device and a manufacturing method of thereof, and more particularly to an electronic device and a manufacturing method of thereof that may reduce the number of transfers of electronic components to be connected in series or may improve the utilization rate of the electronic components on a carrier.

### Description of Related Art

Electronic devices or tiled electronic devices have been widely used in various fields such as communications, displays, automobiles, and aviation. With the rapid development of electronic devices, electronic devices are developing towards being lighter and thinner, which has led to higher requirements for the reliability and the quality of electronic devices.

### SUMMARY

The disclosure is directed to an electronic device and a manufacturing method of thereof that may reduce the number of transfers of electronic components to be connected in series or improve the utilization rate of the electronic components on a carrier.

According to an embodiment of the disclosure, a manufacturing method of an electronic device includes following steps. A carrier and a plurality of electronic components disposed on the carrier are provided, wherein the plurality of electronic components include a first electronic component and a second electronic component. A circuit substrate is provided, wherein the circuit substrate includes a plurality of serial pad combinations, one of the plurality of serial pad combinations includes a first pad, a second pad, a third pad, and a fourth pad, the second pad is electrically connected to the third pad. The first electronic component and the second electronic component are picked up simultaneously. The first electronic component and the second electronic component are simultaneously transferred onto the circuit substrate. The first electronic component is correspondingly disposed on the first pad and the second pad, and the second electronic component is correspondingly disposed on the third pad and the fourth pad, and the first electronic component and the second electronic component are connected in series with each other.

According to an embodiment of the disclosure, an electronic device includes a circuit substrate and a plurality of electronic components. The circuit substrate has a first unit and a second unit. The circuit substrate includes a substrate and a circuit layer disposed on the substrate. The circuit layer includes a first pad, a second pad, a third pad, and a fourth pad. The second pad is electrically connected to the third pad. The plurality of electronic components are disposed on the circuit substrate. The plurality of electronic components include a first electronic component, a second electronic component, and a third electronic component. The first electronic component is disposed on the first pad and the second pad in the first unit. The second electronic component is disposed on the third pad and the fourth pad in the first unit. The third electronic component is disposed on the first pad and the second pad in the second unit. The first pad of the first unit and the third pad are spaced apart by a first distance D1 in a first direction, and the first pad of the first unit and the first pad of the second unit are spaced apart by a second distance D2 in the first direction. The first distance D1, the second distance D2, and a parameter R1 satisfy following relationships: R1 × M1 × 0.9 ≦ D1 ≦ R1 × M1 × 1.1; and R1 × M2 × 0.9 ≦ D2 ≦ R1 × M2 × 1.1. M1 and M2 are positive integers, and M1 is less than M2.

### BRIEF DESCRIPTION OF THE DRAWINGS

FIG. 1 to FIG. 3 are schematic top views of a manufacturing method of an electronic device of the first embodiment of the disclosure.

FIG. 4 shows the position and the order of picking up electronic components from the carrier of FIG. 1.

FIG. 5 is a schematic top view of an electronic device of the second embodiment of the disclosure.

FIG. 6A is a schematic cross-sectional view of the electronic device of FIG. 5 along section line I-I’.

FIG. 6B is a schematic cross-sectional view of the electronic device of FIG. 5 along section line II-II’.

FIG. 6C is a schematic cross-sectional view of the electronic device of FIG. 5 along section line III-III’.

FIG. 6D is a schematic cross-sectional view of the electronic device of FIG. 5 along section line IV-IV’.

FIG. 7 shows the position and the order of picking up electronic components from the carrier in the manufacturing method of the electronic device of FIG. 5.

FIG. 8 is a partial top view of an electronic device of the third embodiment of the disclosure.

FIG. 9 is a partial top view of an electronic device of the fourth embodiment of the disclosure.

### DESCRIPTION OF THE EMBODIMENTS

The disclosure will be understood by referring to the following detailed description in conjunction with the accompanying drawings. It should be noted that, for ease of understanding and for the sake of simplicity of the drawings, many of the drawings in the disclosure depict portions of the electronic device, and certain components in the drawings are not drawn to scale. Furthermore, the number and the dimensions of each of the components in the drawings are for illustrative purposes and are not intended to limit the scope of the disclosure.

In the following specification and claims, the words “including” and “comprising” are open-ended words, and thus should be interpreted as meaning “including but not limited to…”.

It should be understood that when a component or a layer is referred to as being “on” or “connected to” another component or layer, the component or the layer may be directly on or directly connected to the other component or layer, or there may be an intervening component or layer between the two (indirect case). Conversely, when a component is referred to as being “directly on” or “directly connected to” another component or layer, there are no intervening components or layers between the two.

Although the terms “first,” “second,” “third,” etc. may be used to describe various constituting components, the constituting components are not limited to these terms. These terms are used to distinguish a single component from other components within the specification. Claims may not use the same terms, but may be replaced with “first,” “second,” “third,” etc., according to the order in which the components are stated in the claims. Therefore, in the following specification, the first component may be the second component in the claims.

As used herein, the terms “about,” “approximately,” “substantially,” and “roughly” generally mean within 10%, within 5%, within 3%, within 2%, within 1%, or within 0.5% of a given value or range. The quantities given herein are approximate quantities, that is, even without the specific use of “about,” “approximately,” “substantially,” or “roughly,” the meanings of “about,” “approximately,” “substantially,” or “roughly” may still be implied.

In some embodiments of the disclosure, terms related to bonding and connection, such as “connected” and “interconnected,” unless otherwise specified, may refer to two structures being in direct contact, or may also refer to two structures not being in direct contact, with another structure positioned between the two structures. Furthermore, such terms related to bonding and connection may include situations in which both structures are movable or both structures are fixed. Furthermore, the term “coupled” encompasses any direct and indirect connection means.

In some embodiments of the disclosure, an optical microscope (OM), a scanning electron microscope (SEM), an α-step thin film thickness profilometer, an ellipsometer, or other suitable methods may be used to measure the area, the width, the thickness, or the height of each component, or the distance or the spacing between the components. Specifically, according to some embodiments, a scanning electron microscope may be used to obtain a cross-sectional structural image including the component to be measured, and the area, the width, the thickness, or the height of each component, or the distance or the spacing between the components, may be measured.

In the disclosure, an electronic device may include a display device (including a transparent display device), a light-emitting device, a backlight device, a virtual reality device, an augmented reality (AR) device, an antenna device, a sensing device, a tiling device, or any combination thereof, but the disclosure is not limited thereto. The display device may be a non-luminous display or a self-luminous display, depending on the needs, and may be a color display or a monochrome display, depending on the needs. The antenna device may be a liquid-crystal antenna device or a non-liquid-crystal antenna device. The sensing device may be a sensing device sensing capacitance, light, heat, or ultrasound. The tiling device may be a display tiling device or an antenna tiling device, but the disclosure is not limited thereto. Electronic components in the electronic device may include passive components and active components, such as capacitors, resistors, inductors, diodes, transistors, etc. The diode may include a light-emitting diode (LED) or a photodiode. The light-emitting diode may include, for example, an organic light-emitting diode (OLED), a sub-millimeter light-emitting diode (mini LED), a micro LED, or a quantum dot LED, but the disclosure is not limited thereto. The transistor may, for example, include a top-gate thin-film transistor, a bottom-gate thin-film transistor, or a dual-gate thin-film transistor, but the disclosure is not limited thereto. The electronic device may also include a fluorescence material, a phosphor material, a quantum dot (QD) material, or other suitable materials depending on the needs, but the disclosure is not limited thereto. The electronic device may have a peripheral system such as a driving system, a control system, a light source system, etc., to support a display device, an antenna device, a wearable device (for example, including an augmented reality or a virtual reality device), a vehicle-mounted device (for example, including a car windshield), or a tiling device. It should be noted that the electronic device may be any of the above arrangements and combinations, but the disclosure is not limited thereto. The following will use an electronic device as an example to illustrate the content of the disclosure, but the disclosure is not limited thereto.

It should be noted that the following embodiments may be implemented by replacing, recombining, or combining features from several different embodiments to create other embodiments without departing from the spirit of the disclosure. Features of various embodiments may all be arbitrarily mixed and matched as long as they do not violate the spirit of the disclosure or conflict with each other.

Reference will now be made in detail to exemplary embodiments of the disclosure, and examples of the exemplary embodiments are illustrated in the accompanying drawings. Whenever possible, the same reference numerals are used in the drawings and the description to refer to the same or like portions.

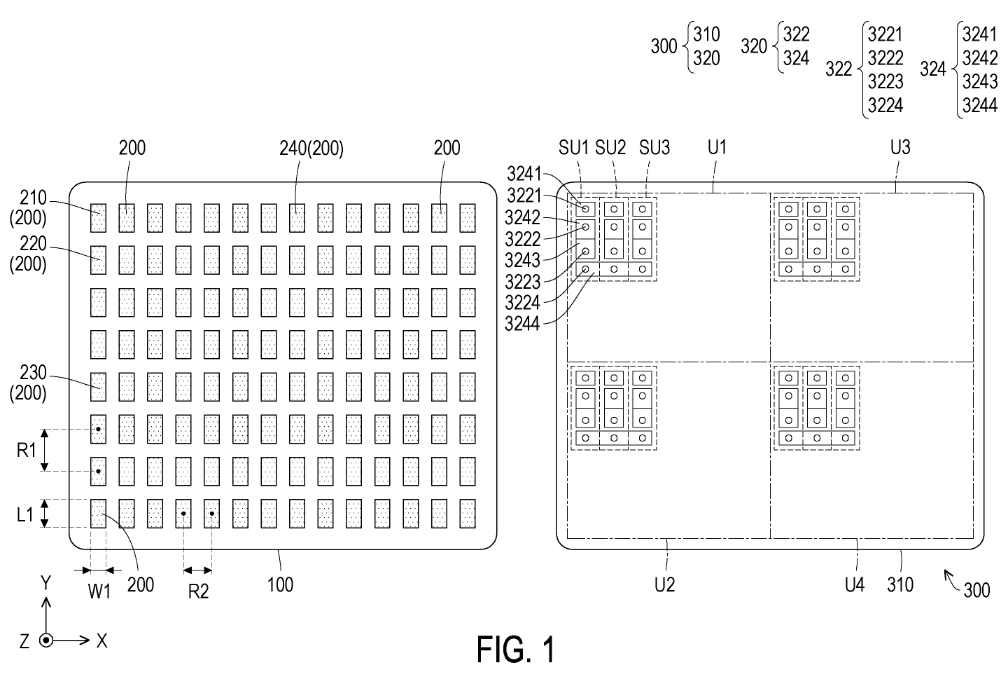

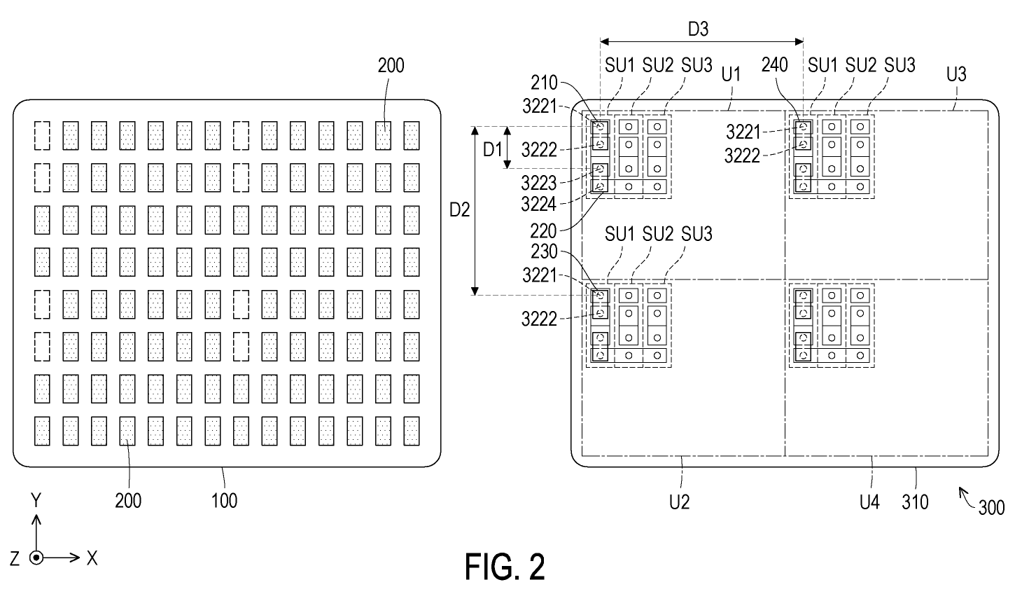

FIG. 1 to FIG. 3 are schematic top views of a manufacturing method of an electronic device of the first embodiment of the disclosure. FIG. 4 shows the positions and the order of picking up electronic components from the carrier of FIG. 1.

The manufacturing method of an electronic device 10 of the present embodiment may include the following steps.

First, referring to FIG. 1, a carrier 100 and a plurality of electronic components 200 are provided. Specifically, the carrier 100 may be a COW (chip on wafer) or a COC (chip on carrier). In the present embodiment, the carrier 100 may include a rigid carrier, a flexible carrier, or a combination thereof. For example, the material of the carrier 100 may include glass, quartz, sapphire, ceramic, polycarbonate (PC), polyimide (PI), polyethylene terephthalate (PET), other suitable carrier materials, or a combination thereof, but the disclosure is not limited thereto.

The plurality of electronic components 200 are disposed on the carrier 100, and the plurality of electronic components 200 may, for example, provide light of the same color. In the present embodiment, the plurality of electronic components 200 are arranged on the carrier 100 in an 8×14 array, for example, but the disclosure is not limited thereto. In the present embodiment, the plurality of electronic components 200 may be red light-emitting components, green light-emitting components, or blue light-emitting components, but the disclosure is not limited thereto.

The plurality of electronic components 200 include a first electronic component 210, a second electronic component 220, a third electronic component 230, and a fourth electronic component 240. One of the plurality of electronic components 200 has a first length L1 in a first direction Y, and one of the plurality of electronic components 200 has a first width W1 in a second direction X. In particular, a first length L1 may be the maximum length of the electronic component 200 measured along the first direction Y, and the first width W1 may be the maximum width of the electronic component 200 measured along the second direction X.

In the present embodiment, a parameter R1 may be the distance between the first repeating features of two adjacent electronic components 200 (e.g., adjacent first electronic component 210 and second electronic component 220) on the carrier 100 measured along the first direction Y, and a parameter R2 may be the distance between the first repeating features of two adjacent electronic components 200 on the carrier 100 measured along the second direction X, but the disclosure is not limited thereto. In the present embodiment, “adjacent” means that there are no other identical components between two identical components, and the “first repeating features” may be, for example, center-to-center or edge-to-edge of two adjacent electronic components on the carrier, but the disclosure is not limited thereto.

In the present embodiment, the parameter R1 may be greater than the first length L1 and less than three times the first length L1 (i.e., L1 < R1 < 3 × L1), and the parameter R2 may be greater than the first width W1 and less than three times the first width W1 (i.e., W1 < R2 < 3 × W1), so that the plurality of electronic components 200 may effectively utilize the space on the carrier 100 and be densely arranged on the carrier 100, but the disclosure is not limited thereto. If the parameter R1 is designed to be greater than or equal to three times the first length L1, or the parameter R2 is designed to be greater than or equal to three times the first width W1, the space on the carrier may not be effectively utilized, thereby increasing manufacturing costs or affecting the yield of electronic components manufactured on the carrier.

In the present embodiment, the first direction Y, the second direction X, and a third direction Z are respectively different directions. The first direction Y is, for example, the direction in which the first length L1 of the electronic components 200 of FIG. 1 is extended. The second direction X is, for example, the direction in which the first width W1 of the electronic components 200 of FIG. 1 is extended. The third direction Z is, for example, the normal direction of the carrier 100. The first direction Y may be substantially perpendicular to the second direction X, and the first direction Y and the second direction X may each be substantially perpendicular to the third direction Z, but the disclosure is not limited thereto.

Next, referring to FIG. 1, a circuit substrate 300 is provided. Specifically, the circuit substrate 300 may include a first unit U1, a second unit U2, a third unit U3, and a fourth unit U4. The first unit U1 and the second unit U2 are arranged along the first direction Y, the third unit U3 and the fourth unit U4 are arranged along the first direction Y, and the first unit U1 and the third unit U3 are arranged along the second direction X. Furthermore, the first unit U1, the second unit U2, the third unit U3, and the fourth unit U4 all include a first sub-unit SU1, a second sub-unit SU2, and a third sub-unit SU3. The first sub-unit SU1, the second sub-unit SU2, and the third sub-unit SU3 are arranged along the second direction X.

The circuit substrate 300 may include a substrate 310 and a circuit layer 320. In the present embodiment, the substrate 310 may include a rigid substrate, a flexible substrate, or a combination thereof. For example, the material of the substrate 310 may include glass, quartz, sapphire, ceramic, polycarbonate, polyimide, polyethylene terephthalate, other suitable substrate materials, or a combination thereof, but the disclosure is not limited thereto.

The circuit layer 320 is disposed on the substrate 310. The circuit layer 320 includes a plurality of serial pad combinations 322 and a plurality of serial circuit combinations 324. The plurality of serial pad combinations 322 are disposed on the plurality of serial circuit combinations 324, and the plurality of serial pad combinations 322 and the plurality of serial circuit combinations 324 are respectively located at different layers. One of the plurality of serial pad combinations 322 may include a first pad 3221, a second pad 3222, a third pad 3223, and a fourth pad 3224. One of the plurality of serial circuit combinations 324 may include a first circuit 3241, a second circuit 3242, a third circuit 3243, and a fourth circuit 3244. The first pad 3221, the second pad 3222, the third pad 3223, and the fourth pad 3224 may respectively be electrically connected to the first circuit 3241, the second circuit 3242, the third circuit 3243, and the fourth circuit 3244. The first pad 3221, the second pad 3222, the third pad 3223, and the fourth pad 3224 may respectively be overlapped with the first circuit 3241, the second circuit 3242, the third circuit 3243, and the fourth circuit 3244 in the third direction Z.

The second pad 3222 may be electrically connected to the third pad 3223. For example, in the present embodiment, the second circuit 3242 may be in contact with and electrically connected to the third circuit 3243. The second pad 3222 may be electrically connected to the third pad 3223 via the second circuit 3242 and the third circuit 3243, and the second pad 3222 and the third pad 3223 may be separated from each other, but the disclosure is not limited thereto. The second circuit 3242 and the third circuit 3243 may be, for example, two portions of the same circuit respectively corresponding to the second pad 3222 and the third pad 3223, but the disclosure is not limited thereto.

Then, referring to FIG. 2, the first electronic component 210, the second electronic component 220, the third electronic component 230 and the fourth electronic component 240 are picked up from the carrier 100 simultaneously; and the picked up first electronic component 210, second electronic component 220, third electronic component 230, and fourth electronic component 240 are transferred onto the circuit substrate 300 simultaneously.

Specifically, after the pick-up and transfer steps, the first electronic component 210 may be correspondingly disposed on the first pad 3221 and the second pad 3222 in the first sub-unit SU1 of the first unit U1, the second electronic component 220 may be correspondingly disposed on the third pad 3223 and the fourth pad 3224 in the first sub-unit SU1 of the first unit U1, the third electronic component 230 may be correspondingly disposed on the first pad 3221 and the second pad 3222 in the first sub-unit SU1 of the second unit U2, and the fourth electronic component 240 may be correspondingly disposed on the first pad 3221 and the second pad 3222 in the first sub-unit SU1 of the third unit U3. In the present embodiment, the first electronic component 210 and the second electronic component 220 transferred onto the circuit substrate 300 may be connected in series with each other. In the disclosure, each of the electronic components 200 has, for example, two electrodes (e.g., a P electrode and an N electrode), wherein the first pad 3221 and the second pad 3222 may respectively correspond to different electrodes of the first electronic component 210, the third pad 3223 and the fourth pad 3224 may respectively correspond to different electrodes of the second electronic component 220, and the second pad 3222 and the third pad 3223 correspond to different electrodes of different electronic components, so that different electronic components may be connected in series. In the present embodiment, a plurality of electronic components connected in series may be driven by the same driving circuit. “Pads of serial pad combinations” and “circuits of serial circuit combinations” respectively refer to pads and circuits allowing a plurality of electronic components to form a series circuit.

In the present embodiment, the first pad 3221 of the first unit U1 and the third pad 3223 of the first unit U1 are spaced apart by a first distance D1 in the first direction Y, the first pad 3221 of the first unit U1 and the first pad 3221 of the second unit U2 are spaced apart by a second distance D2 in the first direction Y, and the first pad 3221 of the first unit U1 and the first pad 3221 of the third unit U3 are spaced apart by a third distance D3 in the second direction X. In the present embodiment, the first distance D1 may be regarded as the minimum distance measured along the first direction Y between the second repeating features of two adjacent electronic components 200 (for example, the adjacent first electronic component 210 and second electronic component 220) in the first unit U1, the second distance D2 may be regarded as the minimum distance measured along the first direction Y between the second repeating features of two adjacent units (for example, the adjacent first unit U1 and second unit U2) in the circuit substrate 300, the third distance D3 may be regarded as the minimum distance measured along the first direction Y between the second repeating features of two adjacent units (for example, the adjacent first unit U1 and third unit U3) in the circuit substrate 300, and the “second repeating features” may, for example, refer to the pads corresponding to the electronic components 200, but the disclosure is not limited thereto.

In some embodiments, the “second repeating features” may also be circuits corresponding to the electronic components 200 or the center point (or the edge) of the electronic components 200 itself. For example, the first distance D1 may also be the distance measured along the first direction Y between the first circuit 3241 corresponding to the first electronic component 210 and the third circuit 3243 corresponding to the second electronic component 220, or the distance measured along the first direction Y between the center point (or the edge) of the first electronic component 210 and the center point (or the edge) of the second electronic component 220. The second distance D2 may also be the distance measured along the first direction Y between the first circuit 3241 corresponding to the first electronic component 210 of the first unit U1 and the first circuit 3241 corresponding to the third electronic component 230 of the second unit U2, or the distance measured along the first direction Y between the center point (or the edge) of the first electronic component 210 of the first unit U1 and the center point (or the edge) of the third electronic component 230 of the second unit U2. The third distance D3 may also be the distance measured along the second direction X between the first circuit 3241 corresponding to the first electronic component 210 of the first unit U1 and the first circuit 3241 corresponding to the fourth electronic component 240 of the third unit U3, or the distance measured along the second direction X between the center point (or the edge) of the first electronic component 210 of the first unit U1 and the center point (or the edge) of the fourth electronic component 240 of the third unit U3.

In the present embodiment, electronic components to be connected in series in the same unit (e.g., the first electronic component 210 and the second electronic component 220) and electronic components of different units (e.g., the first electronic component 210 and the third electronic component 230) may be simultaneously picked up from the carrier 100 and transferred onto the circuit substrate 300, thereby reducing the number of transfers of the electronic component and improving the utilization rate of the electronic components on the carrier. The first distance D1, the second distance D2, and the parameter R1 may satisfy the relationship: R1 × M1 × 0.9 ≦ D1 ≦ R1 × M1 × 1.1, R1 × M2 × 0.9 ≦ D2 ≦ R1 × M2 × 1.1, wherein M1 and M2 are positive integers and M1 < M2 (i.e., the first distance D1 and the second distance D2 on the circuit substrate 300 may be substantially positive integer multiples of the parameter R1 on the carrier 100, and the first distance D1 is less than the second distance D2). In the present embodiment, M1 and M2 may respectively be, for example, 1 and 4 (i.e., the first distance D1 is approximately 1 times the parameter R1, and the second distance D2 is approximately 4 times the parameter R1), but the disclosure is not limited thereto. In the present embodiment, “0.9 times” and “1.1 times” are intended to account for possible process variations in the fabrication of pads (or circuits) or possible bonding variations when the electronic components are bonded to the circuit substrate.

In the present embodiment, the third distance D3 and the parameter R2 may satisfy the relationship: R2 × M3 × 0.9 ≦ D3 ≦ R2 × M3 × 1.1, wherein M3 is a positive integer (i.e., the third distance D3 on the circuit substrate 300 is substantially a positive integer multiple of the parameter R2), thereby reducing the number of transfers he electronic component or improving the utilization rate of the electronic components on the carrier. In the present embodiment, M3 may be, for example, 7 (i.e., the third distance D3 is approximately 7 times the parameter R2), but the disclosure is not limited thereto.

In the present embodiment, there are two multiple relationships (i.e., multiple M1 and multiple M2) in the first direction Y, and one multiple relationship (i.e., multiple M3) in the second direction X, and the total number of multiple relationships (i.e., multiple M1, multiple M2, and multiple M3) may be greater than or equal to 3, which may indicate that there are electronic components connected in series in the same unit of the circuit substrate 300, but the disclosure is not limited thereto.

In the present embodiment, the utilization rate of the electronic components 200 on the carrier 100 may be determined by dividing the total number of all picked-up electronic components 200 by the total number of the electronic components 200 on the carrier 100 before picking up. In the present embodiment, the utilization rate of the electronic components on the carrier may be greater than 0.8, indicating that the carrier has better utilization rate, but the disclosure is not limited thereto. For example, referring to FIG. 4, a grid is used to represent the electronic components 200 arranged in an 8×14 array disposed on the carrier 100 (i.e., the total number of the electronic components 200 on the carrier 100 before picking up is 8×14 = 112), and the numbers in the grid represent the position and the order of picking up the electronic components 200 from the carrier 100. As shown in FIG. 4, during the first pick-up step, eight electronic components 200 may be picked up from the position marked “1” in the figure; then, during the second pick-up step, eight electronic components 200 may be picked up from the position marked “2” in the figure; then, after 14 pick-up steps in order, 112 (8×14) electronic components 200 may be picked up from the carrier 100. Therefore, by dividing the total number (112) of all picked-up electronic components 200 by the total number (112) of the electronic components 200 on the carrier 100 before picking up, it may be seen that the utilization rate of the electronic components 200 on the carrier 100 of the present embodiment may be 1 (112/112).

Then, referring to FIG. 3, similar to the steps shown in FIG. 1 and FIG. 2, electronic components 400 are picked up from another carrier (not shown) and transferred to the second sub-unit SU2 of the first unit U1, the second unit U2, the third unit U3, and the fourth unit U4 of the circuit substrate 300, and electronic components 500 are picked up from another carrier (not shown) and transferred to the third sub-unit SU3 of the first unit U1, the second unit U2, the third unit U3, and the fourth unit U4 of the circuit substrate 300. In particular, two adjacent electronic components 400 in the second sub-unit SU2 may be connected in series with each other, and two adjacent electronic components 500 in the third sub-unit SU3 may also be connected in series with each other. In the present embodiment, the electronic components 200, the electronic components 400, and the electronic components 500 may respectively be light-emitting components providing light of different colors. For example, the electronic components 200 may be red light-emitting components, the electronic components 400 may be green light-emitting components, and the electronic components 500 may be blue light-emitting components, but the disclosure is not limited thereto.

In the present embodiment, although the first unit U1, the second unit U2, the third unit U3, and the fourth unit U4 may all include two electronic components 200 (or electronic components 400, or electronic components 500) connected in series, the disclosure does not limit the number of electronic components that may be connected in series in each unit. In other words, in some embodiments, each unit may also include three or more than three electronic components 200 (or electronic components 400, or electronic components 500) connected in series.

At this point, the electronic device 10 of the present embodiment is substantially completed.

Other embodiments are provided below for illustration purposes. It should be noted that the following embodiments share the same reference numerals and some of the details as the above embodiments, with the same reference numerals used to represent the same or similar components, and descriptions of the same technical details omitted. For the omitted details, please refer to the above embodiments, and the following embodiments will not repeat the omitted details.

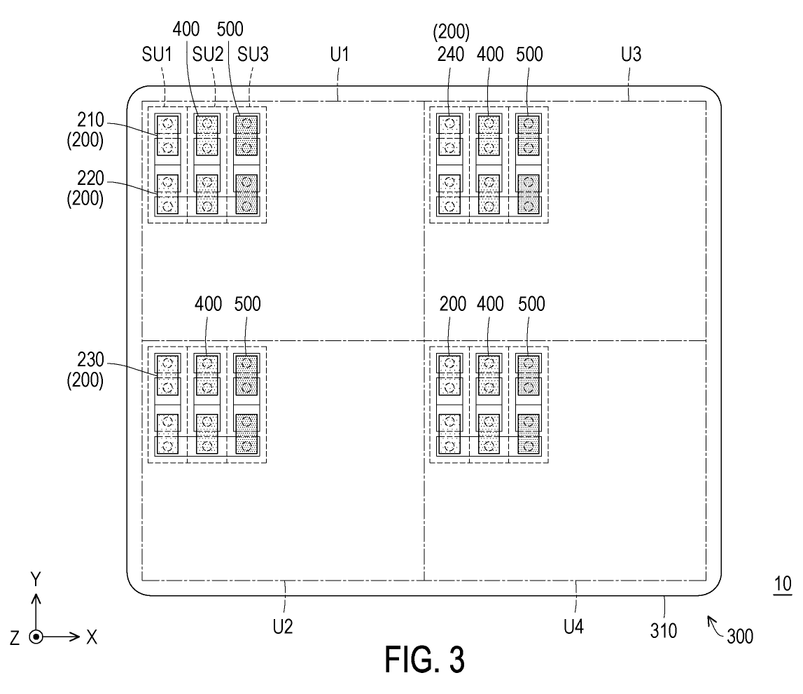

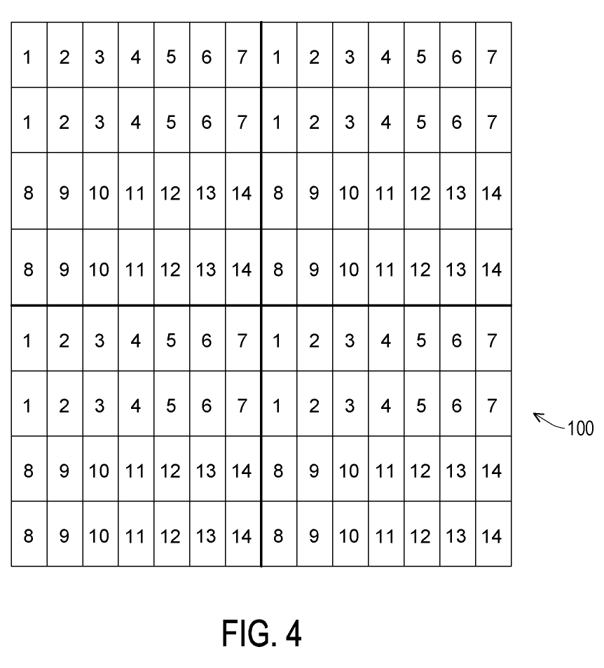

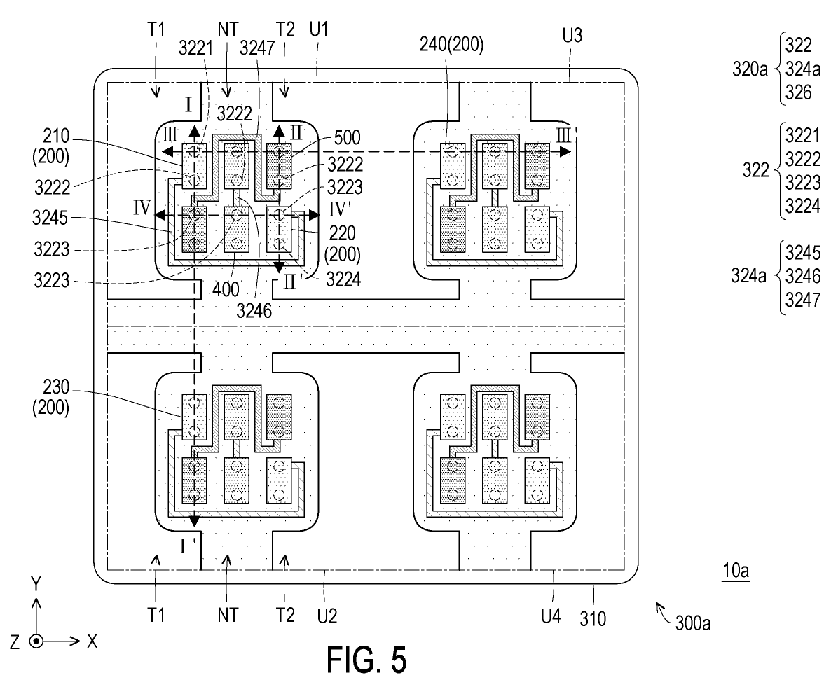

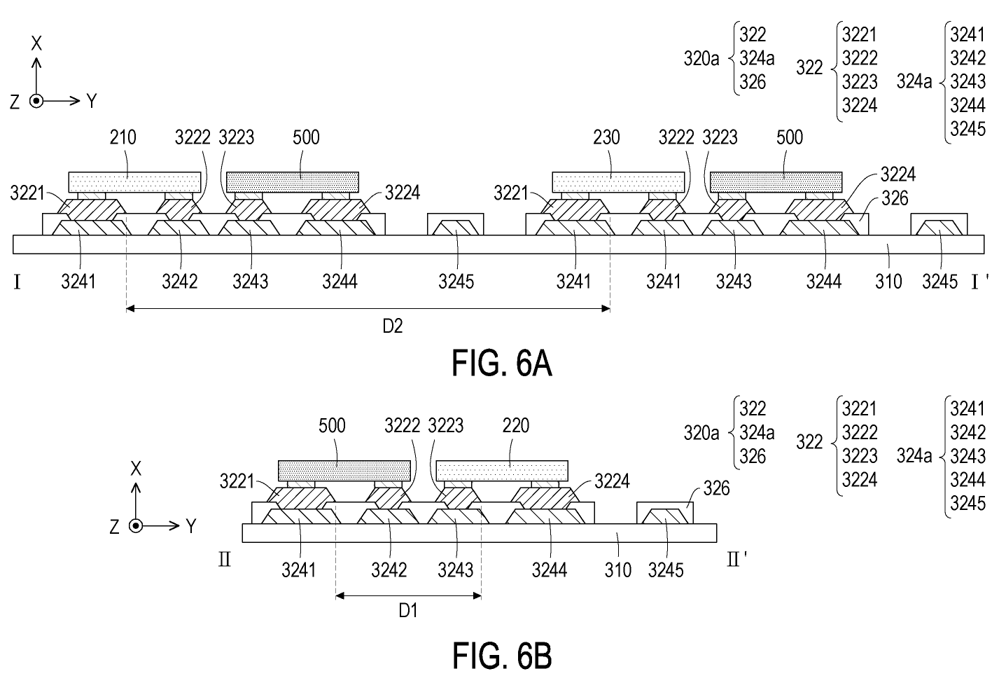

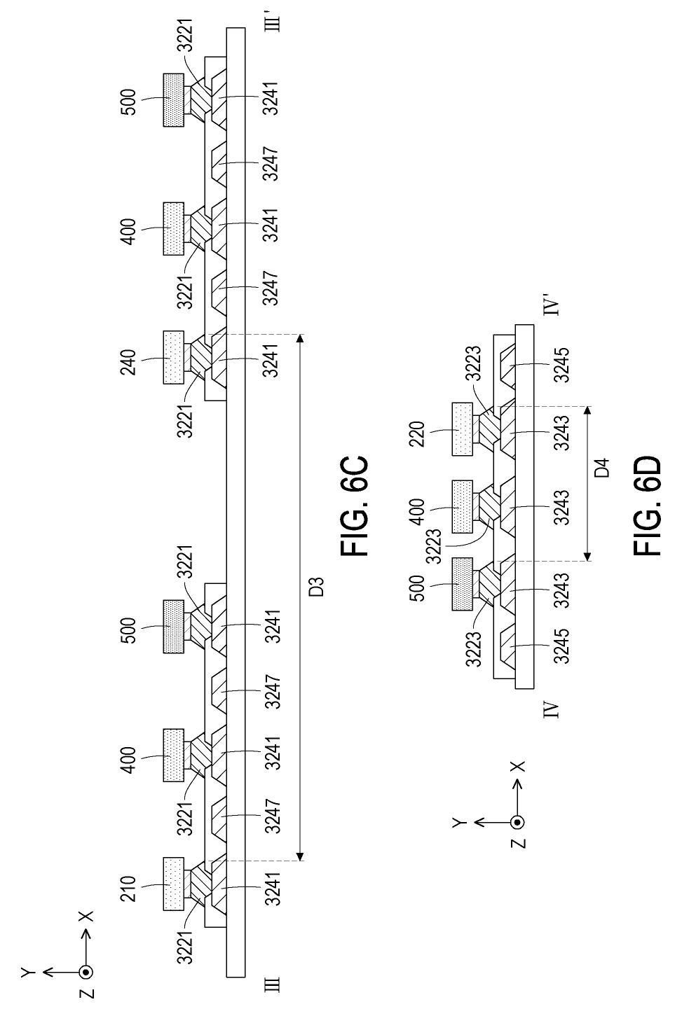

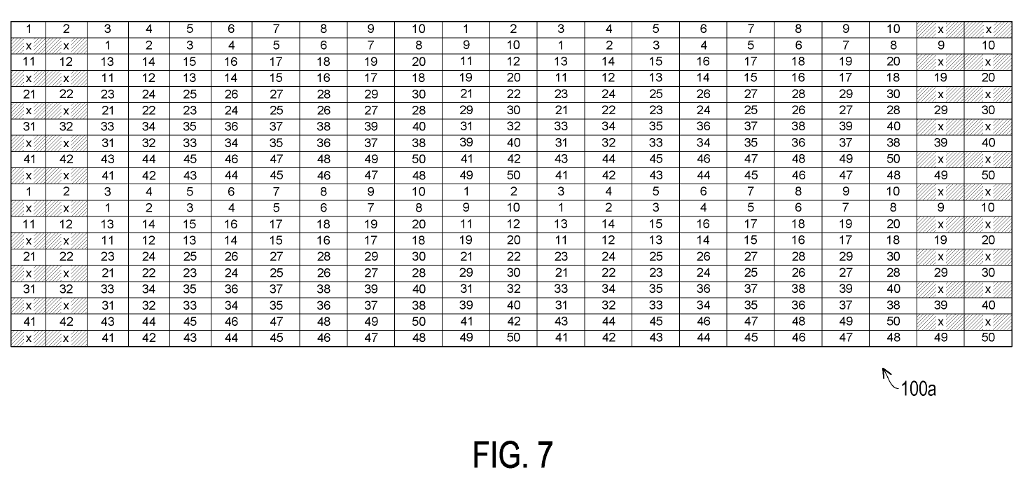

FIG. 5 is a schematic top view of an electronic device of the second embodiment of the disclosure. FIG. 6A is a schematic cross-sectional view of the electronic device of FIG. 5 along section line I-I’. FIG. 6B is a schematic cross-sectional view of the electronic device of FIG. 5 along section line II-II’. FIG. 6C is a schematic cross-sectional view of the electronic device of FIG. 5 along section line III-III’. FIG. 6D is a schematic cross-sectional view of the electronic device of FIG. 5 along section line IV-IV’. FIG. 7 shows the position and the order of picking up electronic components from the carrier in the manufacturing method of the electronic device of FIG. 5. For clarity of the drawings and ease of description, FIG. 5 omits showing some components in an electronic device 10a (for example, a portion of the circuit in a circuit substrate 300a). Referring to FIG. 3, FIG. 4, FIG. 5, and FIG. 7 together, the electronic device 10a of the present embodiment is similar to the electronic device 10 of FIG. 3, and the difference between the two is that: in the electronic device 10a of the present embodiment, each unit (i.e., the first unit U1, the second unit U2, the third unit U3, and the fourth unit U4) of the circuit substrate 300a has a non-transparent area NT and a plurality of transparent areas (i.e., a transparent area T1 and a transparent area T2), and the first electronic component 210 and the second electronic component 220 connected in series in the same unit may be diagonally disposed.

Specifically, referring to FIG. 5, a plurality of transparent areas (i.e., the transparent area T1 and the transparent area T2) may be separated by the non-transparent area NT. The electronic components 200, the electronic components 400, and the electronic components 500 may be disposed corresponding to the non-transparent area NT, and the first pad 3221, the second pad 3222, the third pad 3223, and the fourth pad 3224 may be disposed corresponding to the non-transparent area NT.

Taking the first unit U1 as an example, the first electronic component 210 and the second electronic component 220 connected in series may be diagonally disposed, the two electronic components 400 connected in series may be adjacently disposed in the first direction Y, and the two electronic components 500 connected in series may be diagonally disposed.

Referring to FIG. 5 and FIG. 6A to FIG. 6D together, a circuit layer 320a may include the plurality of serial pad combinations 322, a plurality of serial circuit combinations 324a, and an insulating layer 326. The plurality of serial circuit combinations 324a are disposed on the substrate 310, the insulating layer 326 is disposed on the plurality of serial circuit combinations 324a, and the plurality of serial pad combinations 322 are disposed on the insulating layer 326. The plurality of serial circuit combinations 324a may include the first circuit 3241, the second circuit 3242, the third circuit 3243, the fourth circuit 3244, a fifth circuit 3245, a sixth circuit 3246, and a seventh circuit 3247.

Taking the first unit U1 as an example, the second pad 3222 corresponding to the first electronic component 210 may be electrically connected to the third pad 3223 corresponding to the second electronic component 220 via the fifth circuit 3245, wherein the second pad 3222 corresponding to one of the electronic components 400 may be electrically connected to the third pad 3223 corresponding to another electronic component 400 via the sixth circuit 3246, wherein the second pad 3222 corresponding to one of the electronic components 500 may be electrically connected to the third pad 3223 corresponding to another electronic component 500 via the seventh circuit 3247.

In the present embodiment, as shown in FIG. 6A, the first pad 3221 corresponding to the first electronic component 210 in the first unit U1 and the first pad 3221 corresponding to the third electronic component 230 in the second unit U2 are spaced apart by the second distance D2 in the first direction Y. As shown in FIG. 6B, the first pad 3221 corresponding to the electronic component 500 in the first unit U1 and the third pad 3223 corresponding to the second electronic component 220 in the first unit U1 are spaced apart by the first distance D1 in the first direction Y. As shown in FIG. 6C, the first pad 3221 corresponding to the first electronic component 210 in the first unit U1 and the first pad 3221 corresponding to the fourth electronic component 240 in the third unit U3 are spaced apart by the third distance D3 in the second direction X. As shown in FIG. 6D, the third pad 3223 corresponding to the electronic component 500 in the first unit U1 and the third pad 3223 corresponding to the second electronic component 220 in the first unit U1 are spaced apart by a fourth distance D4 in the second direction X.

In the present embodiment, the third distance D3, the fourth distance D4, and the parameter R2 may satisfy the relationships: R2 × M3 × 0.9 ≦ D3 ≦ R2 × M3 × 1.1 and R2 × M4 × 0.9 ≦ D4 ≦ R2 × M4 × 1.1, wherein M3 and M4 are positive integers and M4 < M3 (i.e., the third distance D3 and the fourth distance D4 on the circuit substrate 300 may be substantially positive integer multiples of the parameter R2 on the carrier 100a, and the fourth distance D4 is less than the third distance D3). Therefore, the number of transfers of the electronic components to be connected in series may be reduced or the utilization rate of the electronic components on the carrier may be improved. In the present embodiment, M3 and M4 may respectively be, for example, 10 and 2 (i.e., the third distance D3 is approximately 10 times the parameter R2, and the fourth distance D4 is approximately 2 times the parameter R2), but the disclosure is not limited thereto. Furthermore, in the present embodiment, the second distance D2 may be equal to the third distance D3, but the disclosure is not limited thereto.

Compared to the first embodiment, the present embodiment has two multiple relationships in the second direction X (i.e., multiple M3 and multiple M4), and the total number of multiple relationships (i.e., multiple M1, multiple M2, multiple M3, and multiple M4) may be greater than or equal to 3, which may indicate that there are electronic components connected in series in the same unit of the circuit substrate 300a, but the disclosure is not limited thereto.

Referring to FIG. 7, a grid is used to represent the electronic components 200 arranged in a 20×22 array disposed on the carrier 100a (i.e., the total number of the electronic components 200 on the carrier 100a before picking up is 20×22 = 440). The numbers in the grid indicate the positions and the order of picking up the electronic components 200 from the carrier 100a, and the “×” in the grid indicates positions where the electronic components 200 are not picked up from the carrier 100a. As shown in FIG. 7, during the first pick-up step, eight electronic components 200 may be picked up from the position marked “1” in the figure, so that the eight picked-up electronic components 200 may be directly transferred onto the circuit substrate 300a of FIG. 5; next, during the second pick-up step, eight electronic components 200 may be picked up from the position marked “2” in the figure, so that the eight picked-up electronic components 200 may be directly transferred onto the circuit substrate 300a or another circuit substrate; then, after 50 pick-up steps in order, 400 (8×50) electronic components 200 may be picked up from the carrier 100a. Therefore, by dividing the total number (400) of all picked-up electronic components 200 by the total number (440) of the electronic components 200 on the carrier 100a before picking up, it may be seen that the utilization rate of the electronic components 200 on the carrier 100a of the present embodiment is approximately 0.91 (400/440).

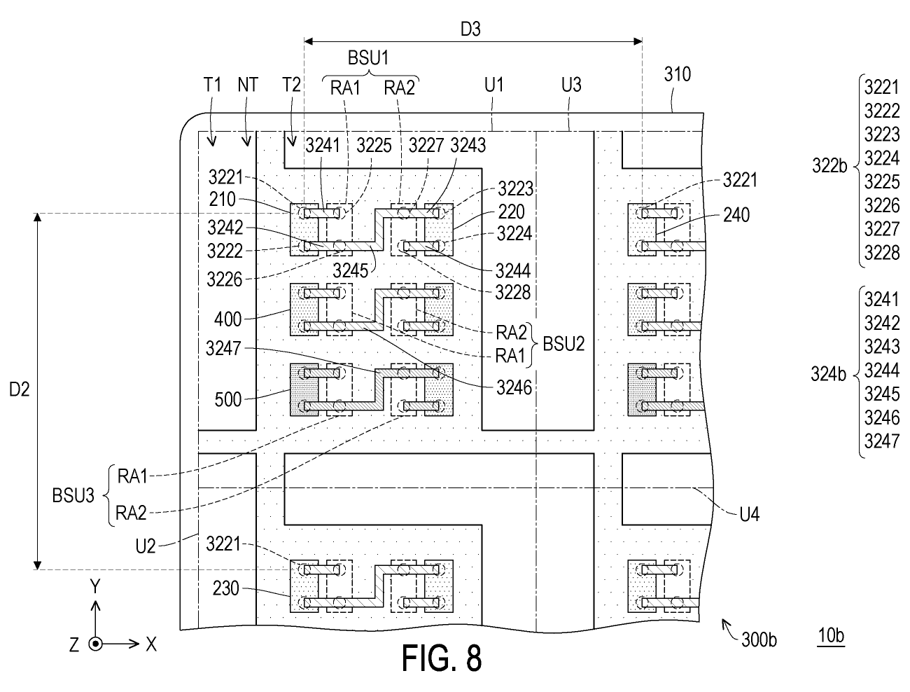

FIG. 8 is a partial top view of an electronic device of the third embodiment of the disclosure. For clarity of the drawings and ease of description, FIG. 8 omits certain components in an electronic device 10b (e.g., portions circuits in a circuit substrate 300b). Referring to FIG. 8 and FIG. 5 together, the electronic device 10b of the present embodiment is similar to the electronic device 10a of FIG. 5, and the difference between the two is that: in the electronic device 10b of the present embodiment, each unit (i.e., the first unit U1, the second unit U2, the third unit U3, and the fourth unit U4) of the circuit substrate 300b further includes a first backup sub-unit BSU1, a second backup sub-unit BSU2, and a third backup sub-unit BSU3.

Specifically, referring to FIG. 8, and the following description will be made by taking the first unit U1 as an example.

The first backup sub-unit BSU1, the second backup sub-unit BSU2, and the third backup sub-unit BSU3 all have a first repair area RA1 and a second repair area RA2. The first repair area RA1 and the second repair area RA2 of the first backup sub-unit BSU1 are disposed between the first electronic component 210 and the second electronic component 220 connected in series, the first repair area RA1 and the second repair area RA2 of the second backup sub-unit BSU2 are disposed between two electronic components 400, and the first repair area RA1 and the second repair area RA2 of the third backup sub-unit BSU3 are disposed between two electronic components 500. In the present embodiment, the backup sub-units (i.e., the first backup sub-unit BSU1, the second backup sub-unit BSU2, and the third backup sub-unit BSU3) may be considered as reserved repair sites, so that if an electronic component is damaged, a new electronic component may additionally be disposed at the first repair area RA1 or the second repair area RA2 of the backup sub-units.

The plurality of serial pad combinations 322b may include the first pad 3221, the second pad 3222, the third pad 3223, the fourth pad 3224, a fifth pad 3225, a sixth pad 3226, a seventh pad 3227, and an eighth pad 3228. The first pad 3221, the second pad 3222, the third pad 3223, and the fourth pad 3224 are disposed in the first sub-unit SU1, the second sub-unit SU2, and the third sub-unit SU3. The fifth pad 3225 and the sixth pad 3226 are disposed in the first backup sub-unit BSU1, the second backup sub-unit BSU2, and the third backup sub-unit BSU3.

The plurality of serial circuit combinations 324b may include the first circuit 3241, the second circuit 3242, the third circuit 3243, the fourth circuit 3244, the fifth circuit 3245, the sixth circuit 3246, and the seventh circuit 3247.

The first pad 3221 corresponding to the first electronic component 210 may be electrically connected to the fifth pad 3225 in the first backup sub-unit BSU1 via the corresponding first circuit 3241, and the second pad 3222 corresponding to the first electronic component 210 may be electrically connected to the sixth pad 3226 in the first backup sub-unit BSU1 via the corresponding second circuit 3242. The third pad 3223 corresponding to the second electronic component 220 may be electrically connected to the seventh pad 3227 in the first backup sub-unit BSU1 via the corresponding third circuit 3243, and the fourth pad 3224 corresponding to the second electronic component 220 may be electrically connected to the eighth pad 3228 in the first backup sub-unit BSU1 via the corresponding fourth circuit 3244. The sixth pad 3226 in the first backup sub-unit BSU1 may be electrically connected to the seventh pad 3227 in the first backup sub-unit BSU1 via the fifth circuit 3245, so that the first electronic component 210 and the second electronic component 220 may be connected in series with each other.

The sixth pad 3226 in the second backup sub-unit BSU2 may be electrically connected to the seventh pad 3227 in the second backup sub-unit BSU2 via the sixth circuit 3246, so that one of the electronic components 400 and another electronic component 400 may be connected in series with each other. The sixth pad 3226 in the third backup sub-unit BSU3 may be electrically connected to the seventh pad 3227 in the third backup sub-unit BSU3 via the seventh circuit 3247, so that one of the electronic components 500 and another electronic component 500 may be connected in series with each other.

In the present embodiment, the first pad 3221 corresponding to the first electronic component 210 in the first unit U1 and the first pad 3221 corresponding to the third electronic component 230 in the second unit U2 are spaced apart by the second distance D2 in the first direction Y. The first pad 3221 corresponding to the first electronic component 210 in the first unit U1 and the first pad 3221 corresponding to the fourth electronic component 240 in the third unit U3 are spaced apart by the third distance D3 in the second direction X. In the present embodiment, the second distance D2 may be equal to the third distance D3, but the disclosure is not limited thereto.

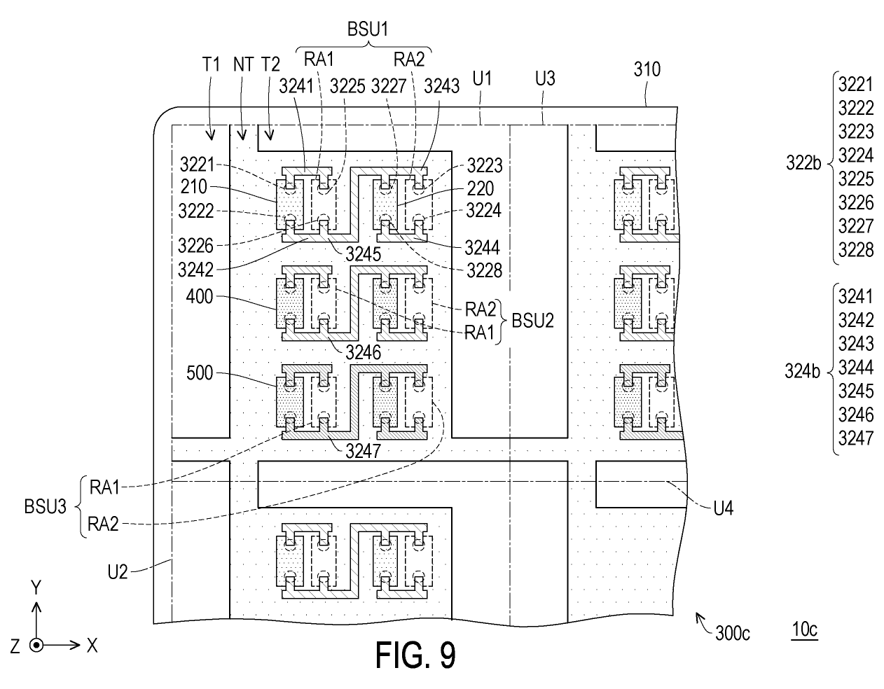

FIG. 9 is a partial top view of an electronic device of the fourth embodiment of the disclosure. Referring to FIG. 9 and FIG. 8 together, an electronic device 10c of the present embodiment is similar to the electronic device 10b of FIG. 8, and the difference between the two is: in the electronic device 10c of the present embodiment, the first repair area RA1 and the second repair area RA2 of the backup sub-units (i.e., the first backup sub-unit BSU1, the second backup sub-unit BSU2, and the third backup sub-unit BSU3) are respectively disposed at the same side of the corresponding electronic component.

Specifically, referring to FIG. 9, the first repair area RA1 and the second repair area RA2 in the first backup sub-unit BSU1 are respectively disposed at the right side of the first electronic component 210 and the right side of the second electronic component 220. The first repair area RA1 and the second repair area RA2 in the second backup sub-unit BSU2 are respectively disposed at the right side of one of the electronic components 400 and the right side of another electronic component 400. The first repair area RA1 and the second repair area RA2 in the third backup sub-unit BSU3 are respectively disposed at the right side of one of the electronic components 500 and the right side of another electronic component 500.

Based on the above, in the electronic device and the manufacturing method thereof of an embodiment of the disclosure, by simultaneously picking up and transferring the first electronic component and the second electronic component to be connected in series onto the circuit substrate, the number of transfers of the electronic components to be connected in series may be reduced, or the utilization rate of the electronic components on the carrier may be improved. Since the first distance and the second distance (or the third distance and the fourth distance) on the circuit substrate may be substantially positive integer multiples of the parameters on the carrier, the first electronic component and the second electronic component to be connected in series in the same unit may be simultaneously picked up from the carrier and simultaneously directly transferred onto the circuit substrate, thereby reducing the number of transfers of the electronic components to be connected in series, or improving the utilization rate of the electronic components on the carrier.

Lastly, it should be noted that each of the above embodiments is used to illustrate the technical solutions of the disclosure, rather than to limit them. Although the disclosure has been described in detail with reference to the above embodiments, those skilled in the art should understand that they may still modify the technical solutions described in each of the above embodiments, or replace some or all of the technical features therein with equivalents. However, these modifications or replacements do not cause the essence of the corresponding technical solutions to deviate from the scope of the technical solution of each of the embodiments of the disclosure.

What is claimed is:

1. A manufacturing method of an electronic device, comprising:
providing a carrier and a plurality of electronic components disposed on the carrier, wherein the plurality of electronic components comprise a first electronic component and a second electronic component;
providing a circuit substrate, wherein the circuit substrate comprises a plurality of serial pad combinations, one of the plurality of serial pad combinations comprises a first pad, a second pad, a third pad, and a fourth pad, and the second pad is electrically connected to the third pad;
picking up the first electronic component and the second electronic component simultaneously; and
transferring the first electronic component and the second electronic component onto the circuit substrate simultaneously,
wherein the first electronic component is correspondingly disposed on the first pad and the second pad, the second electronic component is correspondingly disposed on the third pad and the fourth pad, and the first electronic component and the second electronic component are connected in series with each other.

2. The manufacturing method according to claim 1, wherein the circuit substrate comprises a first unit and a second unit, the first unit and the second unit comprise the plurality of serial pad combinations, the plurality of electronic components further comprise a third electronic component, and the manufacturing method further comprises:
picking up the first electronic component, the second electronic component, and the third electronic component simultaneously;
transferring the first electronic component, the second electronic component, and the third electronic component onto the circuit substrate simultaneously,
wherein the first electronic component is correspondingly disposed on the first pad and the second pad in the first unit, the second electronic component is correspondingly disposed on the third pad and the fourth pad in the first unit, and the third electronic component is correspondingly disposed on the first pad and the second pad in the second unit.

3. The manufacturing method according to claim 2, wherein the first pad in the first unit is spaced apart from the third pad by a first distance D1 in a first direction, the first pad in the first unit is spaced apart from the first pad in the second unit by a second distance D2 in the first direction, and the first distance is less than the second distance.

4. The manufacturing method according to claim 3, wherein the first distance D1, the second distance D2, and a parameter R1 satisfy a relationship:
R1 × M1 × 0.9 ≦ D1 ≦ R1 × M1 × 1.1; and
R1 × M2 × 0.9 ≦ D2 ≦ R1 × M2 × 1.1,
wherein M1 and M2 are positive integers, and M1 is less than M2.

5. The manufacturing method according to claim 4, wherein one of the plurality of electronic components has a first length L1 in the first direction, and L1 < R1 < 3×L1.

6. The manufacturing method according to claim 4, wherein the parameter R1 is a distance in the first direction between first repeating features of two adjacent electronic components in the plurality of electronic components.

7. The manufacturing method according to claim 2, wherein the circuit substrate further comprises a third unit, the third unit comprises the plurality of serial pad combinations, the plurality of electronic components further comprise a fourth electronic component, and the manufacturing method further comprises:
picking up the first electronic component, the second electronic component, the third electronic component, and the fourth electronic component simultaneously;
transferring the first electronic component, the second electronic component, the third electronic component, and the fourth electronic component onto the circuit substrate simultaneously,
wherein the first electronic component is correspondingly disposed on the first pad and the second pad in the first unit, the second electronic component is correspondingly disposed on the third pad and the fourth pad in the first unit, the third electronic component is correspondingly disposed on the first pad and the second pad in the second unit, and the fourth electronic component is correspondingly disposed on the first pad and the second pad in the third unit.

8. The manufacturing method according to claim 7, wherein the first pad in the first unit and the first pad in the third unit are spaced apart by a third distance D3 in a second direction, and the third distance D3 and a parameter R2 satisfy a relationship:
R2 × M3 × 0.9 ≦ D3 ≦ R2 × M3 × 1.1,
wherein M3 is a positive integer.

9. The manufacturing method according to claim 8, wherein one of the plurality of electronic components has a first width W1 in the second direction, and W1 < R2 < 3×W1.

10. The manufacturing method according to claim 8, wherein the parameter R2 is a distance in the second direction between first repeating features of two adjacent electronic components in the plurality of electronic components.

11. The manufacturing method according to claim 10, wherein the first repeating features are a center point or an edge between the two adjacent electronic components.

12. The manufacturing method according to claim 1, wherein a utilization rate of the plurality of electronic components on the carrier is greater than 0.8.

13. An electronic device, comprising:
a circuit substrate having a first unit and a second unit, and comprising a substrate and a circuit layer disposed on the substrate, wherein the circuit layer comprises a first pad, a second pad, a third pad, and a fourth pad, and the second pad is electrically connected to the third pad; and
a plurality of electronic components disposed on the circuit substrate and comprising:
a first electronic component disposed on the first pad and the second pad in the first unit;
a second electronic component disposed on the third pad and the fourth pad in the first unit; and
a third electronic component disposed on the first pad and the second pad in the second unit;
wherein the first pad in the first unit is spaced apart from the third pad by a first distance D1 in a first direction, the first pad in the first unit is spaced apart from the first pad in the second unit by a second distance D2 in the first direction, and the first distance D1, the second distance D2, and a parameter R1 satisfy a relationship:
R1 × M1 × 0.9 ≦ D1 ≦ R1 × M1 × 1.1; and
R1 × M2 × 0.9 ≦ D2 ≦ R1 × M2 × 1.1,
wherein M1 and M2 are positive integers, and M1 is less than M2.

14. The electronic device according to claim 13, wherein one of the plurality of electronic components has a first length L1 in the first direction, and L1 < R1 < 3×L1.

15. The electronic device according to claim 13, wherein the circuit substrate further comprises a third unit, and the plurality of electronic components further comprise:
a fourth electronic component disposed on the first pad and the second pad in the third unit,
wherein the first pad in the first unit and the first pad in the third unit are spaced apart by a third distance D3 in a second direction, and the third distance D3 and a parameter R2 satisfy a relationship:
R2 × M3 × 0.9 ≦ D3 ≦ R2 × M3 × 1.1,
wherein M3 is a positive integer.

16. The electronic device according to claim 15, wherein one of the plurality of electronic components has a first width W1 in the second direction, and W1 < R2 < 3×W1.

17. The electronic device according to claim 13, wherein the plurality of electronic components are used to provide a light of a same color, and the first electronic component and the second electronic component are connected in series with each other.

18. The electronic device according to claim 13, wherein the circuit substrate further comprises a third unit, and the plurality of electronic components further comprise:
a fourth electronic component disposed on the first pad and the second pad in the third unit,
wherein the first pad in the first unit is spaced apart from the first pad in the third unit by a third distance in a second direction, and the third distance is equal to the second distance.

19. The electronic device according to claim 13, wherein the first unit and the second unit have a non-transparent area and a plurality of transparent areas, the plurality of transparent areas are separated by the non-transparent area, and the first pad, the second pad, the third pad, and the fourth pad are disposed corresponding to the non-transparent area.

20. The electronic device according to claim 13, wherein the first unit comprises a first sub-unit and a first backup sub-unit, and the circuit layer further comprises a fifth pad and a sixth pad,
wherein the first pad and the second pad are disposed in the first sub-unit, the fifth pad and the sixth pad are disposed in the first backup sub-unit, the fifth pad is electrically connected to the first pad, and the sixth pad is electrically connected to the second pad.
